(19) United States
(12) Patent Application Publication
(10) Pub. No.: US 2022/0165768 A1
(43) Pub. Date: May 26, 2022

(54) SEMICONDUCTOR DEVICES AND IMAGE SENSORS INCLUDING THE SAME

(71) Applicant: Samsung Electronics Co., Ltd., Suwon-si (KR)

(72) Inventors: SUNGIN KIM, Hwaseong-si (KR); TAEYOUNG SONG, Hwaseong-si (KR); JONGHYUN GO, Seongnam-si (KR)

(21) Appl. No.: 17/465,908

(22) Filed: Sep. 3, 2021

(30) Foreign Application Priority Data
Nov. 23, 2020 (KR) 10-2020-0157647

(51) Int. Cl. H01L 27/146

(52) U.S. Cl. CPC H01L 27/14616; H01L 27/14645; H01L 27/14614; H01L 27/14634; H01L 27/14627; H01L 27/14636; H01L 27/1463; H01L 27/14621

(57) ABSTRACT

Semiconductor devices may include an active fin extending on a substrate in a first direction and including a recess opening both sides located in the first direction, a source region and a drain region respectively adjacent opposing ends of the active fin, a gate electrode traversing the active fin in the second direction, perpendicular to the first direction, on an upper surface of the recess of the active fin, and extending to a side region, adjacent to the recess, and a gate insulating layer between the active fin and the gate electrode. In some embodiments, the first recess may extend through the first active fin in a width direction thereof.

### CROSS-REFERENCE TO RELATED APPLICATION(S)

This application claims priority to Korean Patent Application No. 10-2020-0157647 filed on Nov. 23, 2020 in the Korean Intellectual Property Office, the disclosure of which is incorporated herein by reference in its entirety.

### BACKGROUND

The present inventive concept relates to a semiconductor device and an image sensor having the same.

While demand for high performance, high speed and/or multifunctionality in semiconductor devices has increased, demand for high integration of semiconductor devices has also increased. In order to meet the demand for high integration of semiconductor devices, the development of semiconductor devices having a channel in a three-dimensional (3D) structure has been actively made. For example, as pixels of image sensors are miniaturized, semiconductor devices such as transistors having a reduced area, while maintaining electrical characteristics and reliability, have been introduced.

### SUMMARY

An aspect of the present inventive concept is to provide a semiconductor device having excellent electrical characteristics and reliability despite its small size.

An aspect of the present inventive concept is to provide an image sensor including a semiconductor device, which has excellent electrical characteristics and reliability despite its small size.

According to an aspect of the present inventive concept, a semiconductor device includes: an active tin extending on a substrate in a first direction and including a recess opening both sides located in the first direction; a source region and a drain region respectively located adjacent opposing ends (e.g., at opposing ends) of the active fin; a gate electrode traversing the active fin in the second direction intersecting the first direction, on an upper surface of the recess of the active fin, and extending to a side region, adjacent to the recess; and a gate insulating layer between the active fin and the gate electrode. In some embodiments, the recess may extend through the active fin in a width direction thereof. Further, in some embodiments, the gate electrode may include a first portion in the recess of the active tin and a second portion extending from the first portion onto a side surface of the active fin.

According to another aspect of the present inventive concept, a semiconductor device includes: a source region and a drain region on a substrate and arranged and/or spaced apart from each other in a first direction; an active fin extending in the first direction, connecting the source region and the drain region to each other, and including a recess opened in a second direction intersecting the first direction; a device isolation film on the substrate and surrounding the active fin, the source region, and the drain region; and a gate structure traversing the active fin in the second direction and contacting an upper surface of the recess of the active fin and a side region, adjacent to the recess. In some embodiments, the recess may extend through the active fin in a width direction thereof.

According to another aspect of the present inventive concept, a semiconductor device includes: first to third impurity regions spaced apart from each other; a first active fin connecting the first and second impurity regions and including a first recess opening both sides; a second active fin connecting the first and third impurity regions and including a second recess opening both sides; a first gate electrode traversing the first active fin, on an upper surface of the first recess of the first active fin, and extending to a side region adjacent to the first recess; a first gate insulating layer between the first active fin and the first gate electrode; a second gate electrode traversing the second active fin, on an upper surface of the second recess of the second active fin, and extending to a side region adjacent to the second recess; and a second gate insulating layer between the second active fin and the second gate electrode. In some embodiments_{;} the first recess may extend through the first active fin in a width direction thereof, and the second recess may extend through the second active fin in a width direction thereof.

According to another aspect of the present inventive concept, an image sensor includes: a substrate comprising a first surface and a second surface opposite to the first surface; a photoelectric transformation portion in the substrate and configured to generate electrical charges in response to light incident on the first surface; and a plurality of transistors on the second surface of the substrate and configured to output an electrical signal according to the electrical charge generated by the photoelectric transformation portion, wherein at least one of the plurality of transistors includes: an active fin extending longitudinally in a first direction on the second surface of the substrate and comprising a recess opening both sides located in the first direction; a source region and a drain region respectively adjacent opposing ends (e.g., at opposing ends) of the active fin; a gate electrode traversing the active fin in the second direction intersecting the first direction, on an upper surface of the recess of the active fin, and extending to a side region, adjacent to the recess; and a gate insulating layer between the active fin and the gate electrode. In some embodiments, the first recess may extend through the first active fin in a width direction thereof.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1 is a plan view illustrating a semiconductor device according to an example embodiment of the present inventive concept.

FIGS. 2A to 2C are cross-sectional views of the semiconductor device of FIG. 1, taken along lines X1-X1′, X2-X2′, and Y-Y′, respectively.

FIG. 3 is a schematic perspective view of the semiconductor device of FIG. 1.

FIGS. 4A, 5A, 6A, 7A and 8A are plan views illustrating a method of manufacturing a semiconductor device according to an example embodiment of the present inventive concept.

FIGS. 4B, 5B, 6B, 7B and 8B are cross-sectional views corresponding to FIGS. 4A, 5A, 6A, 7A and 8A taken along an X direction.

FIGS. 4C, 5C, 6C, 7C and 8C are cross-sectional views corresponding to FIGS. 4A, 5A, 6A, 7A and 8A taken along a Y direction.

FIG. 9 is a plan view illustrating a semiconductor device according to an example embodiment of the present inventive concept.

FIGS. 10A. and 1013 are cross-sectional views of the semiconductor device of FIG. 9, taken along lines X-X′ and Y-Y′.

FIGS. 11A and 11B are plan views illustrating a method of manufacturing a semiconductor device according to an example embodiment of the present inventive concept.

FIG. 12 is a cross-sectional view of an active fin in FIG. 11B.

FIG. 13 is a block diagram schematically illustrating an image sensor according to an example embodiment of the present inventive concept.

FIG. 14 is a cross-sectional view of the image sensor of FIG. 13, taken along line D-D′.

### DETAILED DESCRIPTION

Hereinafter, example embodiments of the present inventive concept will be described in detail with reference to the accompanying drawings.

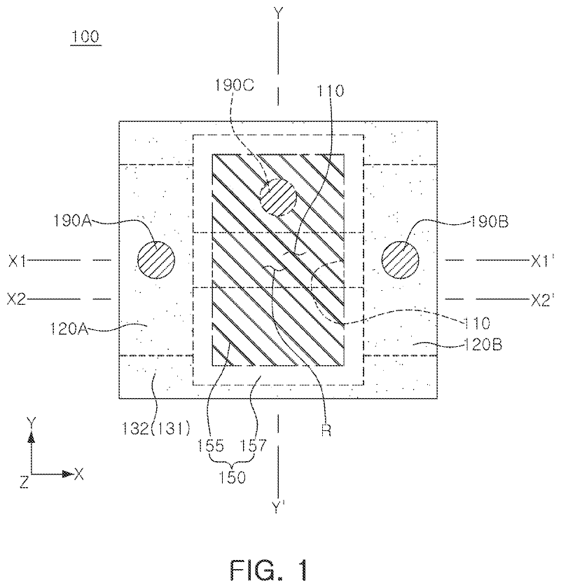

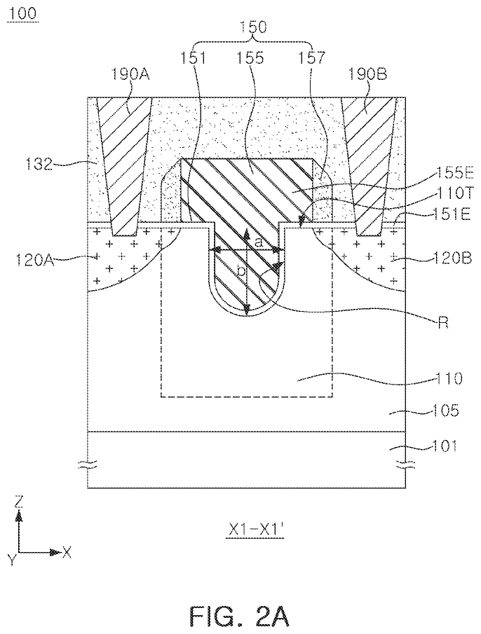

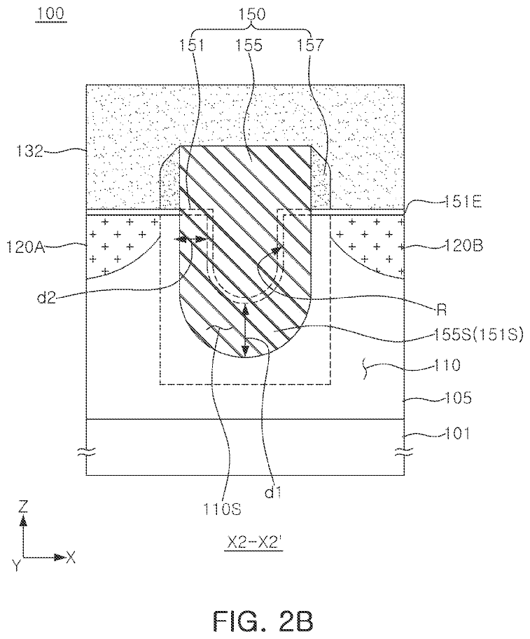

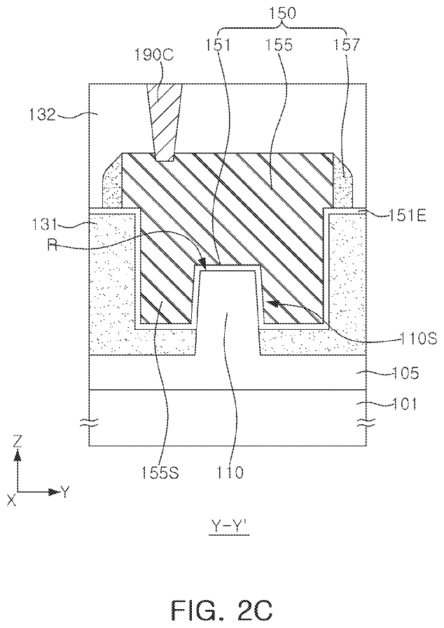

FIG. 1 is a plan view illustrating a semiconductor device according to an example embodiment of the present inventive concept, and FIGS. 2A to 2C are cross-sectional views of the semiconductor device of FIG. 1, taken along lines X1-X1′, X2-X2′, and Y-Y′, respectively.

Referring to FIGS. I and 2A through 2C, a semiconductor device 100 according to the present example embodiment includes a substrate 101 having an active region 105, an active fin 110 disposed in the active region 105 and extending in a first direction (an X direction), and a source region 120A and a drain region 120B respectively disposed in the active region 105 at opposing ends of the active fin 110. The semiconductor device 100 may further include a gate structure 150 extending in a second direction (e.g., a Y direction) substantially perpendicular to the first direction intersecting the active fin 110. As used herein, “an element A extends in a direction X” (or similar language) may mean that the element A extends longitudinally in the direction X. The X direction may be a length direction of the active fin 110, and the Y direction may be a width direction of the active fin 110.

The substrate 101 may include a group IV semiconductor such as Si or Ge, a group compound semiconductor such as SiGe or SiC, or a group III-V compound semiconductor such as GaAs, InAs, or InP. The substrate 101 includes the active region 105. The active region 105 may be a conductive region such as a well doped with impurities or a structure doped with impurities. For example, the active region 105 may be an N-type well for a PMOS transistor or a P-type well for an NMOS transistor. A device isolation film 131 defines the active region 105 having source and drain regions 120A and 120B and the active fin 110. For example, the device isolation film 131 may include an insulating material such as silicon oxide.

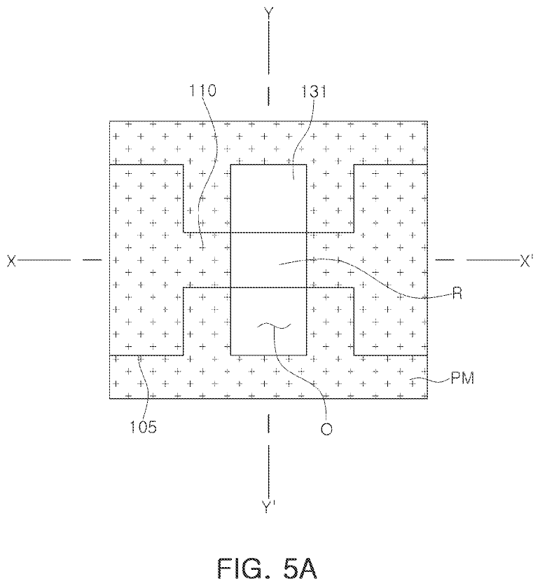

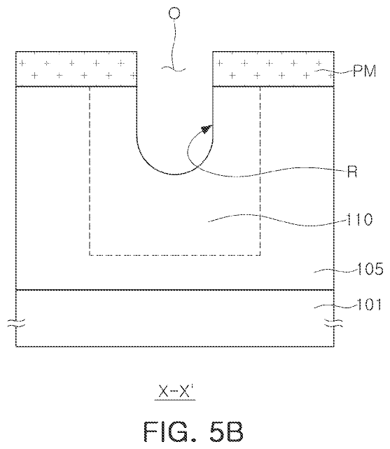

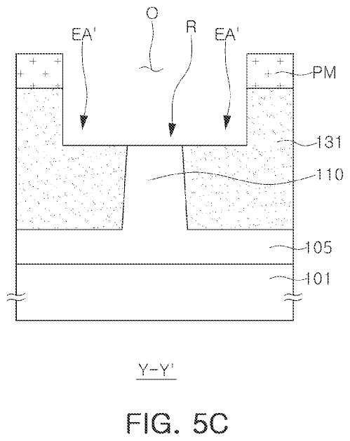

The active fin 110 may be positioned between the source region 120A and the drain region 120B to connect the source region 120A and the drain region 120B. In the present example embodiment, the active fin 110 may have a structure that is raised higher than the active region 105 located on both sides of the active fin 110. The active fin 110 may include portions having upper surfaces substantially coplanar with upper surfaces of the source and drain regions 120A and 120B. The active fin 110 employed in the present example embodiment may have a structure obtained by partially etching the active region 105 having a flat upper surface (see FIGS. 5A to 5C).

In the present example embodiment, the source and drain regions 120A and 120B may have an impurity region doped at a high concentration. The source and drain regions 120A and 120B may be doped with an impurity having the same conductivity type as that of the impurity of the active region 105 (i.e., the active fin). In some example embodiments, the source and drain regions 120A and 120B may include an epitaxial layer obtained by selective epitaxial growth (SEG). For example, the source/drain regions 120A and 120B may be formed by selective epitaxial growth after forming an additional recess in the active fin 110.

The active fin 110 may have a recess R opening both sides of the active fin 110 located in the first direction (e.g., the X direction), The recess R may extend through the active fin 110 in a width direction of the active fin 110, which is in some embodiments the second direction (e.g., the Y direction), as illustrated in FIG. 2C. As shown in FIG. 2A, the recess R of the active fin 110 may have a U-shape in a cross-section in the first direction (e.g., the X direction). A ratio of a depth b of the recess R to an upper width a of the recess R in the first direction (e.g., the X direction) may be in the range of 0.5:1 to 2:1, but the present inventive concept is not limited thereto. For example, the depth b of the recess R may be in the range of 100 to 4000 Å. In some example embodiments, the depth b of the recess R may be in the range of 500 to 1000 Å.

The gate structure 150 may extend in the second direction (e.g., the Y direction), substantially perpendicular to the first direction (e.g., the X direction), so as to traverse a partial region of the active fin 110. The gate structure 150 may include a gate insulating layer 151, a gate electrode 155, and a gate spacer 157. The gate electrode 155 may be disposed on a surface of the recess R of the active fin 110. Additionally, the gate electrode 155 may have a portion 155S extending onto a side region 1105 adjacent to the recess R of the active fin 110. For example, the gate electrode 155 may include polysilicon, TiN, TaN, WCN, or combinations thereof. A portion of the gate structure 150 including the portion 1555 of the gate electrode 155 may cover the side region 110S of the active fin 110. In some embodiments, the portion of the gate structure 150 including the portion 155S of the gate electrode 155 may contact the side region 1105 of the active fin 110 as illustrated in FIG. 2C.

As described above, not only the surface of the recess R of the active fin 110 but also the side region 1105 adjacent to the recess R of the active fin 110 may be provided as an extended channel region.

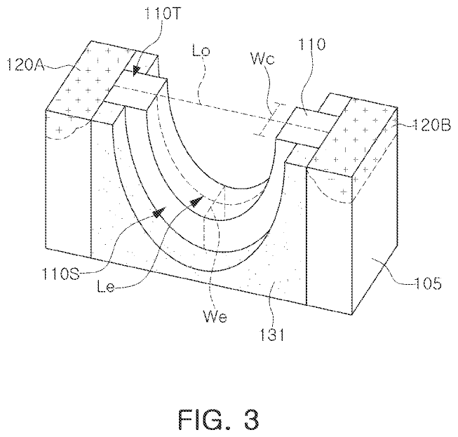

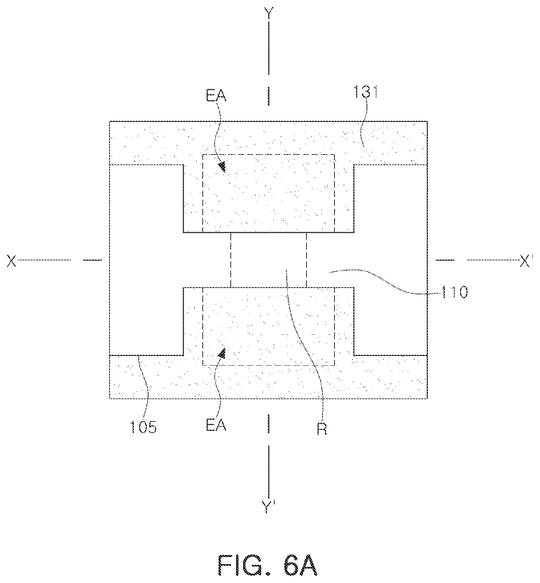

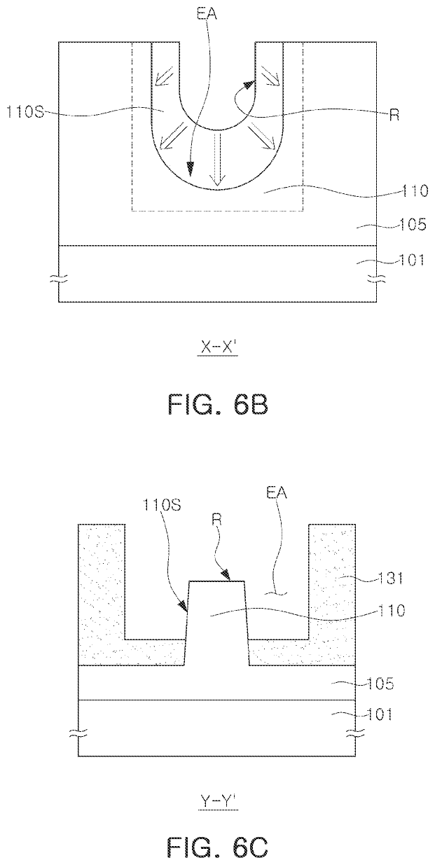

FIG. 3 is a schematic perspective view of the semiconductor device of FIG. 1. In FIG. in order to show the structure of the active fin 110 employed in the present example embodiment, the gate structure 150 is omitted from view. The active fin 110 in which the recess R is not formed has a channel length of “L0” in the first direction, whereas the active fin 110 in which the recess R is formed has a channel length Le extending along a surface of the recess R. In addition, the channel width of the active fin in which the recess is not formed is Wc, whereas the active fin 110 employed in the present example embodiment may have a channel width We extending to the partial region 1105 on both sides adjacent along the recess R. The expansion of the channel width We may be defined by the device isolation film 131. For example, the channel width may be expanded through additional selective etching on the device isolation film 131 after the process of forming the recess R in the active fin 110 (see FIGS. 6A to 6C).

As shown in FIG. 2B, the side region 1105 adjacent to the recess R may be provided with a U-shape similar to a cross-sectional shape of the recess R. For example, widths d1 and d2 of the side region 1105 adjacent to the recess R may be 100 Å or more. In the side region 110s adjacent to the recess R, the width d1 of a portion adjacent to a lower end of the recess R may be greater than the width d2 of a portion adjacent to an upper end of the recess R.

In the present example embodiment, the gate electrode 155 may have a portion 155E extending onto an upper surface region 110T adjacent to the recess R of the active fin 110. The portion 155E of the gate electrode 155 may cover the upper surface region 110T adjacent to the recess R of the active fin 110. As shown in FIG. 2A, the gate electrode 155 may have a substantially T-shaped structure.

The gate insulating layer 151 may be disposed between the active fin 110 and the gate electrode 155. In the present example embodiment, the gate insulating layer 151 may have a portion 151E extending onto partial regions of the source/drain regions 120A and 120B and to the device isolation film 131. The gate insulating layer 151 may be formed of a single dielectric layer or may include a plurality of dielectric layers.

In some example embodiments, the gate insulating layer 151 nay include a first gate insulating layer and a second gate insulating layer disposed on the first gate insulating layer. For example, the first gate insulating layer may include silicon oxide. For example, the second gate insulating layer may include a high-k material. In some example embodiments, the second gate insulating layer may include hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, lead zinc niobate, or combinations thereof.

The gate spacer 157 may be disposed on the side of the gate electrode 155. For example, the gate spacer 157 may include silicon oxide, silicon nitride, silicon oxynitride, silicon carbonitride, silicon oxycarbonitride, or combinations thereof. In some example embodiments, the gate spacer 157 may include a plurality of layers formed of different materials.

The semiconductor device 100 according to the present example embodiment may include an interlayer insulating part 132 and first to third contacts 190A, 190B, and 1900, The interlayer insulating part 132 may be disposed on the device isolation film 131 to cover the source/drain regions 120A and 120B and the gate structure 150. The first and second contacts 190A and 190B may be connected to the source/drain regions 120A and 120B, respectively, through the interlayer insulating part 132, and similarly, the third contact 190C may be connected to the gate electrode 155 through the interlayer insulating part. For example, the interlayer insulating part 132 may include silicon nitride, silicon oxide, or silicon oxynitride. In some example embodiments, the interlayer insulating part 132 may be tetraethylorthosilicate (TEOS), undoped silicate glass (USG), phosphosilicate glass (PSG), borosilicate glass (BSG), baro phosphosilicate glass (BPSG), fluoride silicate glass (FSG), spin on glass (SOG), tonen silazene (TOSZ), or combinations thereof. The interlayer insulating part 132 may be formed using a chemical vapor deposition (CVD) or spin coating.

In the present example embodiment, the first to third contacts 190A, 190B, and 190C may include a conductive barrier and a contact plug disposed on the conductive barrier. In some example embodiments, the conductive barrier may be a conductive metal nitride film. For example, the conductive barrier may include TiN, TaN, AlN, WN, and combinations thereof. For example, the contact plug may include tungsten (W), cobalt (Co), titanium (Ti), alloys thereof, or combinations thereof.

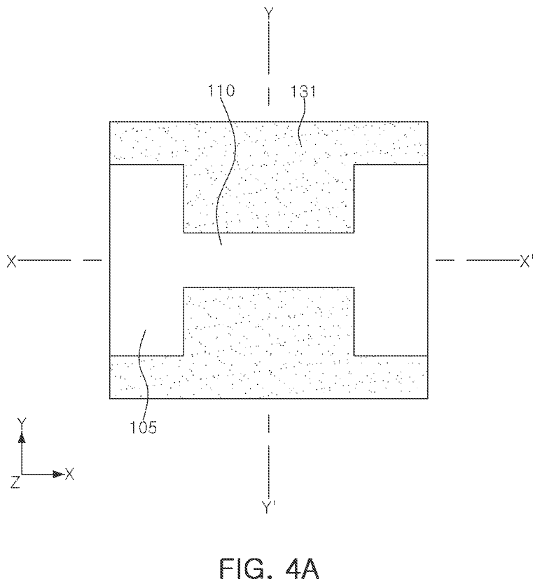

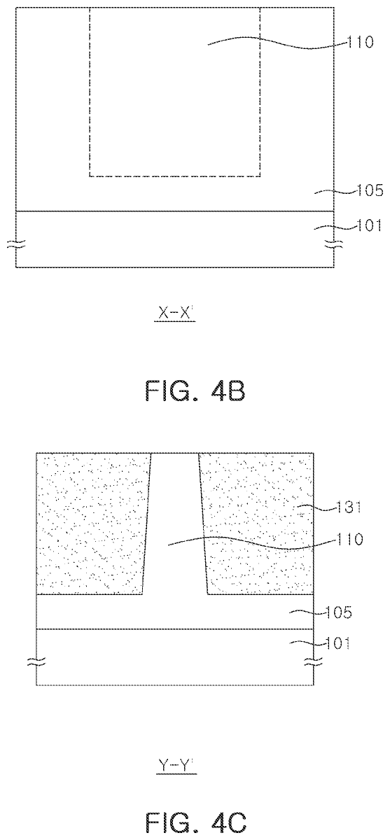

FIGS. 4A, 5A, 6A, 7A and 8A are plan views illustrating a method of manufacturing a semiconductor device according to some example embodiments of the present inventive concept. FIGS. 4B, 5B, 6B, 7B and SB are cross-sectional views corresponding to FIGS. 4A, 5A, 6A, 7A and 8A taken along an X direction, and FIGS. 4C, 5C, 6C, 7C and 8C are cross-sectional views corresponding to FIGS. 4A to 8A taken along a Y direction. The method of manufacturing a semiconductor device according to the present example embodiment may be understood as a method of manufacturing the semiconductor device shown in FIGS. 1 through 2C.

First, referring to FIGS. 4A to 4C, the substrate 101 having the active region 105 having the active fin 110 and the device isolation film 131 surrounding the active fin 110 is prepared.

The active fin 110 may extend in the first direction (e.g., the X direction). A width of the active fin 110 in the second direction (e.g., the Y direction) may be narrower than a width of the active regions 105 located at both ends of the active fin 110. The active regions 105 located at both ends of the active fin 110 may be provided as a source region and a drain region in a follow-up process. In the present example embodiment, the active fin 110 may be a structure obtained by etching the active region 105. The active fin 110 may have an upper surface substantially coplanar with an upper surface of the active region 105 for source and drain regions. The active region 105 may be a p-type or n-type impurity region.

The device isolation film 131 may be formed to surround the active fin 110 to define the active fin 110. In this step, the device isolation film 131 may have an upper surface substantially coplanar with an upper surface of the active region 105 having the active fin 110. Although not shown in the present example embodiment, the device isolation film 131 may define the active region 105, In some example embodiments, the device isolation film 131 may include a shallow trench isolation (STI) region defining the active fin 110 and a deep trench isolation (DTI) region defining the active region 105. The device isolation film 131 may include an insulating material such as silicon oxide. For example, the device isolation film 131 may be TEOS, USG, PSG, BSG, BPSG, FSG, SOG, TOSZ, or combinations thereof.

Next, referring to FIGS. 5A to 5C, a mask pattern PM having an opening O defining the recess R may be formed, and the recess R may be formed in the active fin 110 using the mask pattern PM.

In this process, the opening O of the mask pattern PM may be formed to expose a partial region of the device isolation film 131 additionally adjacent thereto in addition to a partial region of the active fin 110 in which the recess R is to be formed. Referring to FIG. 5A, the opening O has a shape (e.g., rectangle) of traversing a partial region of the active fin 110 in the second direction the Y direction)) to open partial regions of the device isolation film 131 adjacent to both sides of the active fin 110.

After selective etching using the mask pattern PM, the active fin 110 may have the recess R opening both sides of the active fin 110 located in the first direction (e.g., the X direction). The recess R may extend through the active fin 110 in a width direction thereof, which in some embodiments is the second direction (e.g., the Y direction), as illustrated in FIG. 5C. The recess R of the active fin 110 may have a U shape in a cross-section (see FIG. 5B) in the first direction (e.g., the X direction). Partial regions of the device isolation film 131 adjacent to both sides of the active fin 110 may also be removed to form a preliminary recess region EA′ (see FIG. 5C).

Next, referring to FIGS. 6A to 6C, the recess region EA formed in the device isolation film 131 may be expanded using selective etching.

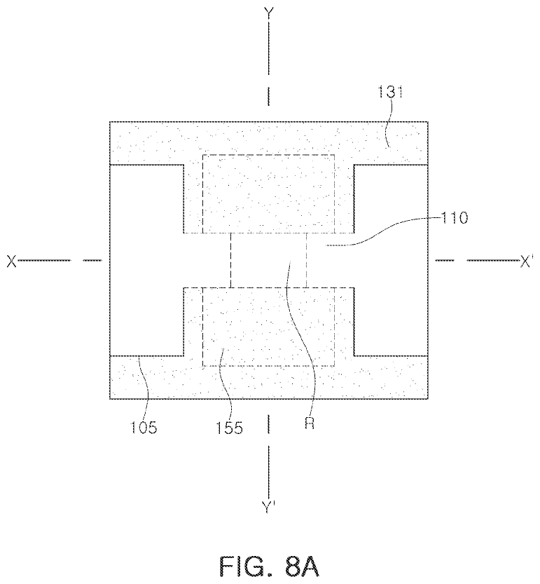

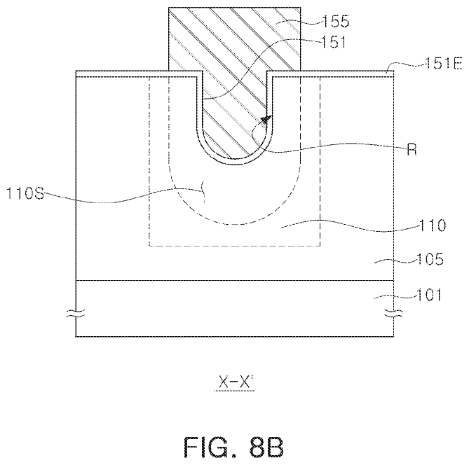

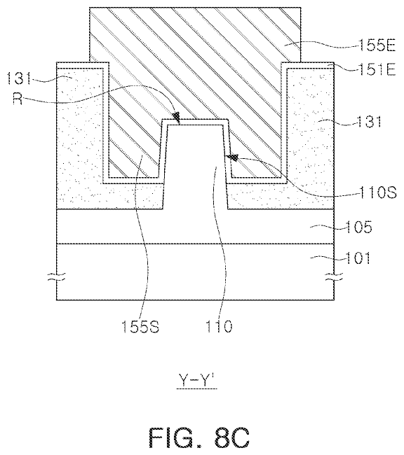

In this process, the preliminary recess region EA′ of the device isolation film 131 obtained in the previous process may be additionally etched using an etching process having high selectivity with respect to a material of the active fin 110. In this selective etching process, the recess region EA of the device isolation film 131 may be expanded to additionally expose both side regions 110S of the active fin 110. As illustrated in FIGS. 8B and 8C, the exposed side region 110s of the active fin 110 is additionally positioned to be adjacent to the recess R of the active fin 110 and may be disposed continuously with an upper surface of the recess R. In a cross section (see FIG. 8B) in the first direction (e.g., the X direction), the exposed side region 110S of the active fin 110 may have a U shape similar to the shape of the recess R. In this manner, the exposed side region 110S of the active fin 110 may be provided as an extended channel region together with the upper surface of the recess R of the active fin 110. In order to sufficiently expand the channel width, the additionally exposed side region 110S may have a width of 100 Å or more. In the exposed side region 110s, a width of a portion adjacent to the lower end of the recess R may be greater than a width of a portion adjacent to the upper end of the recess R.

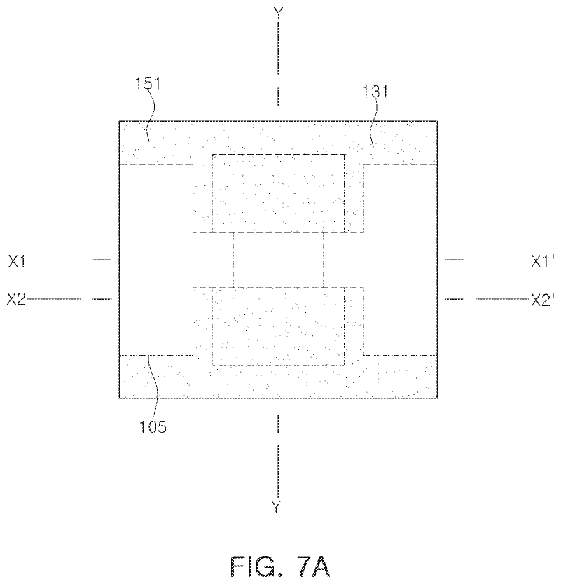

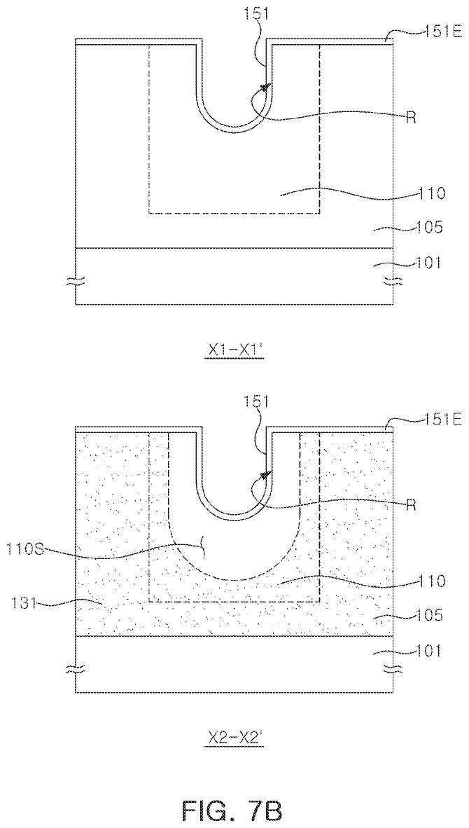

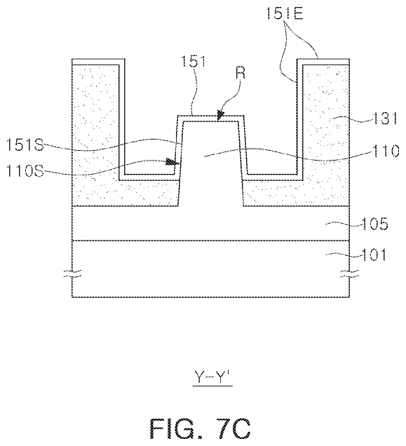

Next, referring to FIGS. 7A to 7C, the gate insulating layer 151 may be formed to cover the surface of the exposed active fin 110.

In this process, the gate insulating layer 151 may be conformally formed on the exposed surface of the active fin 110, that is, on the surface of the recess R of the active fin 110 and the exposed side region 1105. In the present example embodiment, the gate insulating layer 151 may have the portion 151E extending onto partial regions of the source/drain regions 120A and 12013 and onto the device isolation film 131 and may have the portion 1515 extending onto the exposed side region 110S. The gate insulating layer 151 may be formed by physical vapor deposition (PVD), chemical vapor deposition (CVD), and/or atomic layer deposition (ALD). As used herein the term “and/or” includes any and all combinations of one or more of the associated listed items.

In the present example embodiment, the gate insulating layer 151 may include a first gate insulating layer and a second gate insulating layer disposed on the first gate insulating layer. For example, the first gate insulating layer may include silicon oxide. For example, the second gate insulating layer may include a high-k material. In some example embodiments, the second gate insulating layer may include hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, lead zinc niobate, or combinations thereof.

Next, referring to FIGS. 8A through 8C, the gate electrode 155 may be formed at a region of the gate insulating layer 151 located at the active fin 110.

Additionally, the gate electrode 155 may extend in the second direction (e.g., the Y direction), while partially covering a region including the recess R of the active fin 110. The gate electrode 155 may be disposed on a surface of the recess R of the active fin 110 and extend onto the side region 1105 adjacent to the recess R of the active fin 110. For example, the gate electrode 155 may include polysilicon, TiN, TaN, W, WCN, or combinations thereof. The gate electrode 155 may have an extending portion on an upper surface adjacent to the recess R of the active fin 110. The gate electrode 155 employed in the present example embodiment may have a substantially I shape in the cross-section as shown in FIG. 8B.

The source and drain regions (120A and 120B of FIGS. 1, 2A and 2B) may be formed using a follow-up process (e.g., ion implantation and diffusion process/gate spacer formation process). In some example embodiments, low-concentration impurity regions may be formed in the active regions 105 on both sides of the gate electrode 155. For example, in the case of a PMOS transistor, the low-concentration impurity region may be doped with a p-type impurity such as boron (B). A partial region of the low-concentration impurity region may extend below the gate electrode 155 due to impurity diffusion, After forming the gate spacer 157 on a side wall of the gate electrode 155, a high-concentration impurity region may be formed in the low-concentration impurity region. For example, the high-concentration impurity region may be formed by implanting a P-type impurity, for example, boron (B), using an ion implantation process. Subsequently, after the interlayer insulating part 132 is formed, the first and second contacts 190A and 190B connected to the source and drain regions 120A and 120B through the interlayer insulating part 130 and the third contact 190C connected to the gate electrode 155 through the interlayer insulating part 130 may be formed (see FIGS, 2A through 2C).

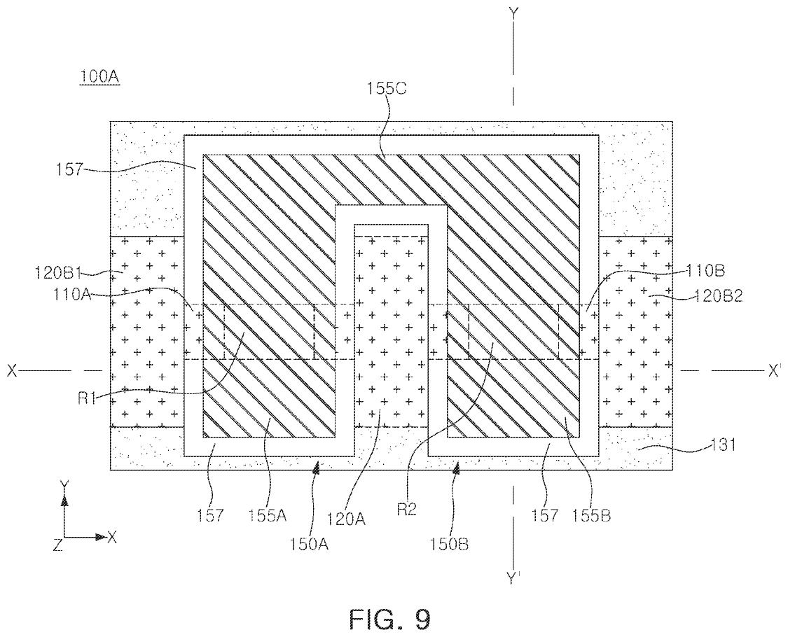

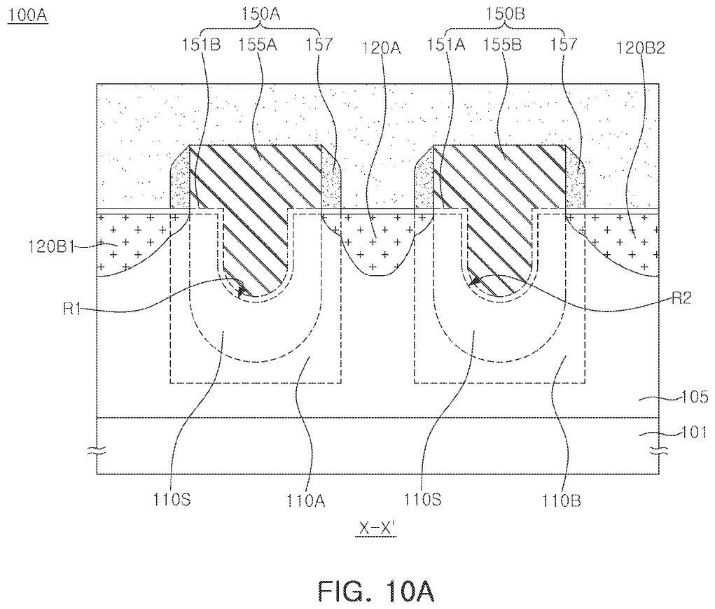

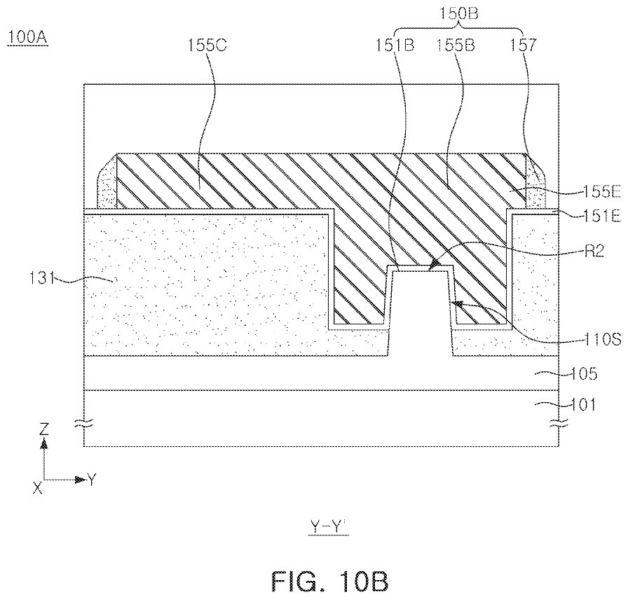

FIG. 9 is a plan view illustrating a semiconductor device according to an example embodiment of the present inventive concept, and FIGS. 10A and 10B are cross-sectional views of the semiconductor device of FIG. 9 taken along lines X-X′ and Y-Y′.

Referring to FIGS. 9, 10A, and 1013, a semiconductor device 100A according to the present example embodiment may have a structure in which two transistors share a source region or a drain region. Each transistor may be understood as having a structure similar to the example embodiment shown in FIGS. 1 and 2A through 2C, and unless otherwise specified, the description of the example embodiment shown in FIGS. 1 and 2A through 2C may be combined with the description of the present example embodiments.

The semiconductor device 100A according to the present example embodiment includes first to third high-concentration impurity regions 120A, 120B1, and 120B2 disposed to be spaced apart from each other in the active region 105, a first active fin 110A connecting the first and second high-concentration impurity regions 120A and 120B1, and a second active fin 110B connecting the first and third high-concentration impurity regions 120A and 120B2.

The first high-concentration impurity region 120A may be provided as a source region shared by the first and second transistors, and the second and third high-concentration impurity regions 120B1 and 120B2 may be provided as drain regions of the first and second transistors, respectively.

The first active fin 110A may have a first recess R1 opening both sides thereof. The first recess R1 may extend through the first active fin 110A in a width direction thereof, which is in some embodiments the second direction (e.g., the Y direction). Similarly, the second active fin 110B may have a second recess R2 opening both sides thereof. The second recess R2 may extend through the second active fin 110B in a width direction thereof, which is in some embodiments the second direction (e.g., the Y direction) as illustrated in FIG. 10B. As shown in FIG. 10A, the first and second recesses 110A and 110B may each have a U-shape,

The first and second gate electrodes 155A and 155B may be disposed in the first and second recesses R1 and R2, respectively, and extend to traverse the first and second active fins 110A and 110B. Additionally, the first and second gate electrodes 155A and 155B may extend onto the side regions 1105 adjacent to the first and second recesses R1 and R2, respectively. The first gate insulating layer 151A may be disposed between the first active fin 110A and the first gate electrode 155A, and similarly, the second gate insulating layer 151B may be disposed between the second active fin 110B and the second gate electrode 155B.

As such, the channel region extended to not only the surfaces of the first and second recesses R1 and R2 of the first and second active fins 110A and 110E but also the side regions 1105 of the first and second active fins 110A and 110B adjacent to the first and second recesses R1 and R2 may be provided.

In the present example embodiment, the first and second gate electrodes 155A. and 155B are illustrated as being interconnected by a bridge gate electrode 1550, but the present inventive concept is not limited thereto. For example, without the bridge gate electrode 1551, the first and second gate electrodes 155A and 155B may be separated into individual gate electrodes. Although separated as individual gate electrodes, the first and second gate electrodes 155A and 155B may be interconnected by a backside wiring structure in some example embodiments.

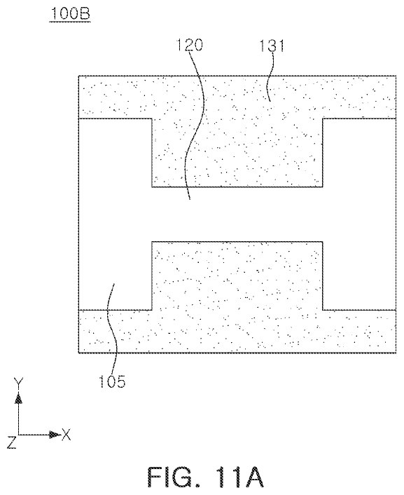

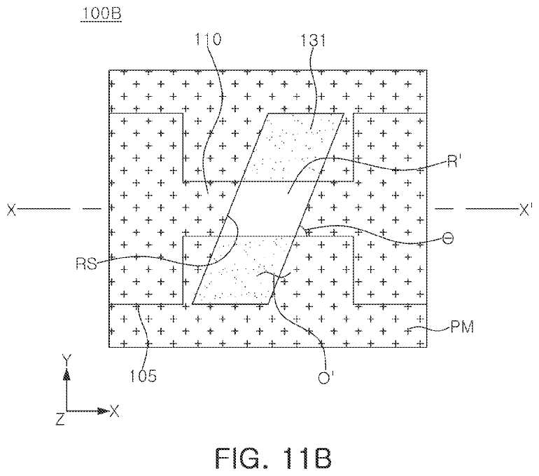

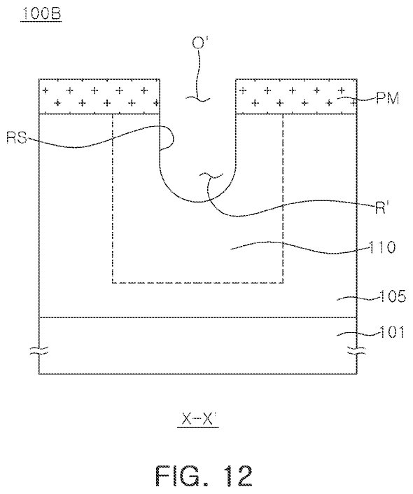

FIGS. 11A and 11B are plan views illustrating a method of manufacturing a semiconductor device according to an example embodiment of the present inventive concept, and FIG. 12 is a cross-sectional view of an active fin formed in FIG. 11B.

The semiconductor device 100B according to the present example embodiment may be understood as having a structure similar to that of the semiconductor device 100 illustrated in FIGS. 1 through 3, except that a direction in which the recess R′ is formed is inclined with respect to a direction in which the active fin 110 extends, Components of the present example embodiment may be understood with reference to descriptions of the same or similar components of the semiconductor device 100 shown in FIGS. 1 through 3 unless otherwise specified.

First, referring to FIGS. 11A and 11B, similar to FIGS. 4A and 4B, a substrate 101 having an active region 105 having an active fin 110 and a device isolation film 131 surrounding the active fin 110 may be prepared, and a recess R′ may be formed at the active fin 110 using a mask pattern PM having an opening O′ defining the recess R′.

Unlike the previous example embodiment, the opening O′ of the mask pattern PM is provided to be inclined with respect to, rather than being perpendicular to, the direction in which the active fin extends, that is, the first direction (e.g., the X direction), and an internal side surface RS of the recess formed by the opening O′ may have an inclined surface in a plan view. The inclined recess employed in the present example embodiment may provide a surface of the channel region as a crystal plane different from that of the previous example embodiment. As such, a crystal plane of the inner side surface RS of the active fin 110 to be provided as a channel region may be selected using an inclination angle O of the recess R′ from a plan view (see FIG. 11B). For example, in a case in which the substrate 101 is a silicon substrate, an inclined recess R′ may be introduced to select a crystal plane having fewer defects such as a (100) plane.

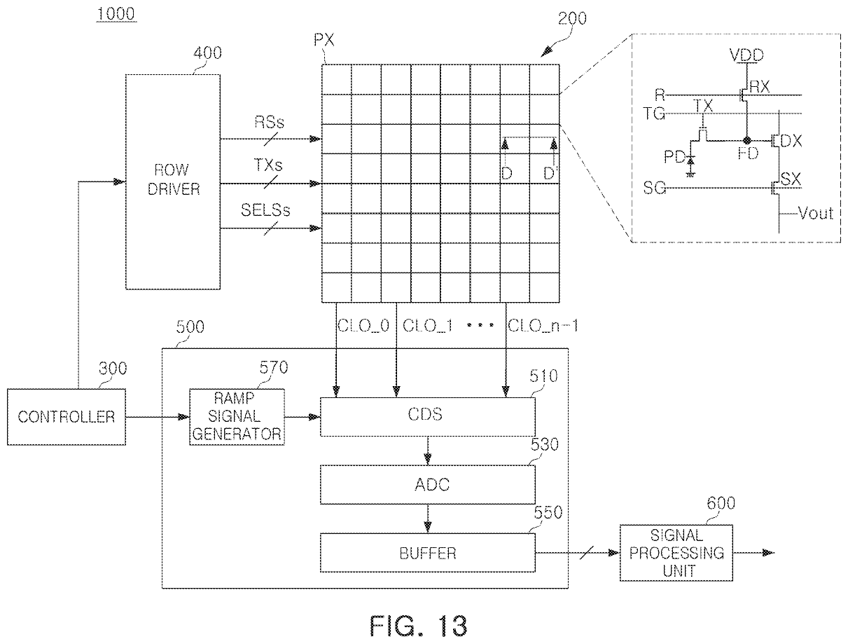

FIG. 13 is a block diagram schematically illustrating an image sensor according to an example embodiment of the present inventive concept.

Referring to FIG. 13, an image sensor 1000 according to the present example embodiment may include a pixel array 200, a row driver 400, and a signal reader 500. The row driver 400 and the signal reader 500 may be configured to be driven by the controller 300.

The pixel array 200 may include a plurality of pixels PX arranged in a matrix form in a row direction and a column direction. Each of the pixels PX may include a corresponding photoelectric transformation device PD. For example, the photoelectric transformation device PD may be a photodiode. The plurality of pixels PX may absorb light to generate electrical charges, and an electrical signal (e.g., an output voltage) according to the generated electrical charges may be provided to the signal reader 500.

The plurality of pixels PX may include a transfer transistor TX and logic transistors RX, SX, and DX, together with the photoelectric transformation device PD. Here, the logic transistors may include a reset transistor (RX), a selection transistor (SX), and a drive transistor or source follower transistor (DX). In the present example embodiment, at least one of the aforementioned transistors may be implemented as the semiconductor devices 100 and 100B according to the example embodiments described above.

Gate electrodes of the transfer transistors TX, the reset transistor RX, and the selection transistor SX may be connected to driving signal lines TG, RG, and SG, respectively. The transfer transistors TX may be connected to the photoelectric transformation device PD. In some example embodiments, two or more adjacent transfer transistors TX may share a floating diffusion region (FD) (or a charge detection node). The photoelectric transformation devices PD may generate and accumulate photocharges in proportion to the amount of light incident from the outside. In some example embodiments, the photoelectric transformation device PD may be implemented as a photo transistor, a photo gate, a pinned photo diode (PPD), and combinations thereof, in addition to a photo diode.

The transfer transistor TX transfers the electrical charges accumulated in the photoelectric transformation device PD to the charge detection node FD, that is, a floating diffusion region. Signals complementary to each other may be applied to the transfer gate TG. The drive transistor DX may be controlled according to the amount of photocharges accumulated. in the charge detection node FD. The reset transistor RX may periodically reset the electrical charges accumulated in the charge detection node FD. In detail, a drain electrode of the reset transistor RX is connected to the floating diffusion region FD, and a source electrode is connected to a power source voltage VDD. When the reset transistor RX is turned on, the power source voltage VDD connected to the source electrode of the reset transistor RX is transferred to the floating diffusion region FD. Accordingly, when the reset transistor RX is turned on, electrical charges accumulated in the floating diffusion region FD are discharged to reset the floating diffusion region FD. The drive transistor DX is combined with a constant current source (not shown) located outside a unit pixel PX to serve as a source follower buffer amplifier, amplifies a potential change in the floating diffusion region FD, and outputs the same to an output line Vout. The selection transistor SX may select unit pixels PX to be read in row units. When the selection transistor SX is turned on, an electrical signal output to a drain electrode of the drive transistor DX may be transmitted to a drain electrode of the selection transistor SX.

The operation of the pixel array 200 (e.g., absorbing light to accumulate an electrical charge, temporarily storing the accumulated electrical charge, and outputting an electrical signal according to the stored electrical charge) is controlled through the row driver 400. The row driver 400 may generate control signals RSs, TXs, and. SELSs and provide the generated control signals RSs, TXs, and SELSs to driving signal lines TG, RG, and SG of the plurality of pixels PX, respectively, to control the pixel array 200. The row driver 400 may determine activation and deactivation timing of the reset control signals RSs, transmission control signals TXs, and selection signals SELSs for the plurality of pixels PX.

The signal reader 500 may include a correlated double sampler (CDS) 510, an analog-to-digital converter (ADC) 530, and a buffer 550. The CDS 510 may sample and hold an output voltage provided from the pixel array 200. The CDS 510 may double sample a specific noise level and a level according to the generated output voltage, and output a level corresponding to a difference therebetween. In addition, the CDS 510 may receive ramp signals generated by a ramp signal generator 570, compare the signals, and output a comparison result. The ADC 530 may convert an analog signal corresponding to a level received from the CDS 510 into a digital signal. The buffer 550 may latch the digital signal, and latched signals may be sequentially output externally through a signal processing unit 600.

The signal processing unit 600 may perform signal processing on received data of the plurality of pixels PX. The signal processing unit 600 may process various image signals for image quality improvement such as noise reduction processing, gain adjustment, waveform shaping processing, color filter array interpolation, white balance processing, gamma correction, edge enhancement processing, etc. In addition, the signal processing unit 600 may perform a phase difference operation using information on the plurality of pixels PX when phase difference autofocusing is performed. In the present example embodiment, the signal processing unit 600 is illustrated to be realized at a part (e.g., logic circuit unit) of the image sensor 1000, but the signal processing unit 600 may also be realized as an external processor (not shown) separately provided outside.

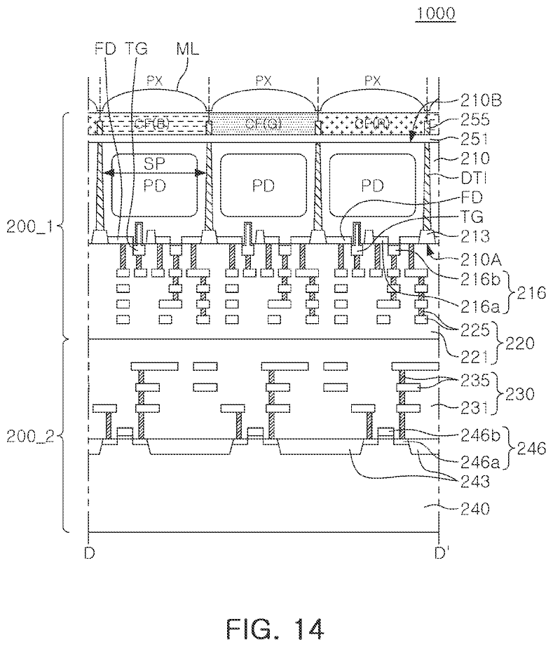

FIG. 14 is a cross-sectional view of the image sensor 1000 of FIG. 13, taken along line D-D′.

Referring to FIG. 14, the image sensor 1000 may include a first chip 200_1 and a second chip 200_2. The first chip 200_1 may be an image sensor chip in which a plurality of pixels PX are arranged, and the second chip 200_2 may be a logic semiconductor chip. In this disclosure, only the first chip 200_1 may be referred to as an “image sensor.”.

The first chip 200_1 may include a first substrate 210 having a first surface 210A and a second surface 210B located opposite to each other and a first wiring structure 220 disposed on the first surface 210A of the first substrate 210. For example, the first substrate 210 may include a group IV semiconductor such as Si or Ge, a group IV-IV compound semiconductor such as SiGe or SiC, or a group III-V compound semiconductor such as GaAs, InAs, or InP.

The first substrate 210 may include a device isolation pattern DTI defining pixels PX and photoelectric transformation devices PD disposed in each pixel PX. For example, the photoelectric transformation devices PD may generate and accumulate electrical charges in proportion to the amount of light incident from the second surface 210B of the first substrate 210. The first photoelectric transformation devices PD may be formed inside the first substrate 210. For example, the photoelectric transformation devices PD may be realized as a photo transistor, a photo gate, a pinned photo diode (PPD) and combinations thereof, in addition to a photo diode. In some embodiments, the photoelectric transformation devices PD may be a photo transistor, a photo gate, a PPD and/or a photo diode.

The first substrate 210 may include a device isolation portion 213 disposed on the first surface 210A together with the photoelectric transformation devices PD to define an active region, a transfer gate TG and a floating diffusion region FD disposed in the active region, and first individual devices 216 formed in the active region. The transfer gate TG may have a vertical transistor gate structure extending from a surface of the active region of the first substrate 210, i.e., from the first surface 210A, into the first substrate 210, and the floating diffusion region FD may be formed in an active region adjacent to the transfer gate TG. A transistor including the transfer gate TG is also referred to as a transfer transistor (e.g., TX in FIG. 13) connected to the photoelectric transformation device PD. The first individual devices 216 may include a transistor having impurity regions 216a provided as source/drain and a gate structure 216b. The transistor 216 may include a reset transistor, a selection transistor, and/or a source follower transistor.

As described above, various transistors disposed on the first surface 210A of the first substrate 210 may output an electrical signal according to electrical charges generated by the photoelectric transformation devices PD. At least one of these various transistors ay be realized as the semiconductor devices 100 and 100B described in the previous example embodiments.

The first wiring structure 220 may include a first insulating layer 221 and a first multilayer wiring 225 formed in the first insulating layer 221 and connected to the first individual devices 216. The first multilayer wiring 225 may include a plurality of wiring layers positioned at different height levels and vias electrically connecting the plurality of wiring layers and/or the first individual devices 216.

The second chip 200_2 includes a second substrate 240 and a second wiring structure 230 disposed on the second substrate 240. For example, similar to the first substrate 210, the second substrate 240 may include a group IV semiconductor such as Si or Ge, a group IV-IV compound semiconductor such as SiGe or SiC, or a group III-V compound semiconductor such as GaAs, InAs, or MP The second substrate 240 includes a device isolation portion 243 defining an active region and second individual devices 246 formed on the active region. The second individual devices 246 may be a logic circuit for image processing and may be, for example, a transistor device having impurity regions 246a provided as source/drain and a gate structure 246b. The second wiring structure 230 may include a second insulating layer 231 and a second multilayer wiring 235 formed in the second insulating layer 231 and connected to the second individual devices 246. The second multilayer wiring 235 may include a plurality of wiring layers positioned at different height levels and vias electrically connecting the plurality of wiring layers and/or the second individual devices 246.

The image sensor 1000 according to the present example embodiment may include an insulating layer 251, color filters CF, and microlenses ML sequentially disposed on the second surface 210B of the first substrate 210. The insulating layer 251 may be formed to cover the second surface 210B of the first substrate 210 between the second surface 210B of the substrate 210 and the color filters CF. The insulating layer 251 may include an antireflection layer. In some example embodiments, the insulating layer 251 may additionally include a planarization layer. For example, the insulating layer 251 may include at least one or two or more layers of an aluminum oxide, a hafnium oxide, a silicon oxide, and a silicon nitride.

A light blocking pattern 255 may be disposed on the insulating layer 251 to define pixels PX. The light blocking pattern 255 may vertically overlap the device isolation ern DTI. The light blocking pattern 255 may be disposed to not vertically overlap the photoelectric transformation device PD in each pixel PX. For example, the light blocking pattern 255 may include a metal such as tungsten.

The color filters CF may be respectively disposed in regions defined by the light blocking patterns 255 to provide pixels PX1 for image sensing. The color filters CF may include a blue (B) color filter, a green (G) color filter, and a red (R) color filter. In the present example embodiment, the color filters CF may vertically overlap one photoelectric transformation device PD disposed in one pixel PX, respectively. The color filters CF may allow light having a specific wavelength different from each other to generate electrical charge from light having a specific wavelength in the photoelectric transformation device PD positioned therebelow. The color filters CF may be arranged in a Bayer-type pattern. The Bayer-type pattern may be arranged such that green (G) filters CF, to which human eyes react most sensitively, are half of all color filters.

As described above, even if the area for implementing transistors for a circuit for generating and processing image signals is reduced due to a reduction in a pixel size SP in the image sensor 1000, since both the channel width and the channel length are extended by introducing the U-shaped recess in the active fin, thereby forming transistors that ensure excellent characteristics (e.g., noise characteristics).

According to the present example embodiment, by introducing the recess structure to the active pin, both the channel width and the channel length may be extended despite the reduction in the device area, whereby the semiconductor device capable of ensuring excellent electrical characteristics and reliability may be provided. In particular, the semiconductor device may be advantageously used in an image sensor requiring a reduction in the area of a transistor device due to a reduction in size of pixels.

While example embodiments have been shown and described above, it will be apparent to those skilled in the art that modifications and variations could be made without departing from the scope of the present inventive concept as defined by the appended claims.

1. A semiconductor device comprising:
an active fin extending longitudinally in a first direction and including a recess that extends through the active fin in a width direction thereof;
a source region and a drain region respectively adjacent opposing ends of the active fin;
a gate electrode traversing the active fin in a second direction, the gate electrode comprising a first portion in the recess of the active fin and a second portion extending from the first portion onto a side surface of the active fin; and
a gate insulating layer between the active fin and the gate electrode.

2. The semiconductor device of claim 1, wherein the recess of the active fin has a U shape in a cross-section in the first direction.

3. The semiconductor device of claim 2, wherein the side surface of the active fin comprises a portion onto which the second portion of the gate electrode extends, and the portion of the side surface of the active fin has a U shape.

4. The semiconductor device of claim 1, wherein a ratio of a depth of the recess to a width of an upper end of the recess in the first direction is in a range of from 0.5:1 to 2:1.

5. The semiconductor device of claim 1, wherein the recess of the active fin has a depth ranging from 100 to 4000 Å.

6. The semiconductor device of claim 1, wherein the side surface of the active fin comprises a portion onto which the second portion of the gate electrode extends, and the portion of the side surface of the active fin has a width of 100 Å or greater.

7. The semiconductor device of claim 6, wherein the side surface of the active fin comprises a portion onto which the second portion of the gate electrode extends, and the portion of the side surface of the active fin has a first width adjacent to a lower end of the recess and has a second width adjacent to an upper end of the recess, and the first width is wider than the second width.

8. The semiconductor device of claim 1, wherein an uppermost surface of the active fin is substantially coplanar with upper surfaces of the source region and the drain region.

9. The semiconductor device of claim 1, wherein the gate electrode further comprises a third portion extending from the first portion of the gate electrode onto an upper surface of the active fin.

10. The semiconductor device of claim 1, wherein the side surface of the active fin is a first side surface, and the active fin further comprises a second side surface defining the recess, and the second side surface of the active fin is slanted with respect to the first direction in a plan view.

11. (canceled)

12. A semiconductor device comprising:
a source region and a drain region on a substrate and spaced apart from each other in a first direction;
an active fin extending in the first direction, connecting the source region and the drain region to each other, and including a recess that extends through a width direction of the active fin;
a device isolation film on the substrate and surrounding the active fin, the source region, and the drain region; and
a gate structure traversing the active fin in a second direction and comprising a first portion in contact with a surface of the recess of the active fin and a second portion extending from the first portion onto a side surface of the active fin.

13. The semiconductor device of claim 12, wherein the recess of the active fin has a depth ranging from 100 to 4000 Å, and
the side surface of the active fin comprises a portion onto which the second portion of the gate structure extends, and the portion of the side surface of the active fin has a width of 100 Å or greater.

14. The semiconductor device of claim 12, wherein the gate structure includes a gate electrode on the surface of the recess of the active fin and on the side surface of the active fin, a gate insulating layer between the active fin and the gate electrode, and a gate spacer on a side surface of the gate electrode.

15. (canceled)

16. The semiconductor device of claim 14, wherein the second portion of the gate structure comprises a portion of the gate electrode, and the portion of the gate electrode has a first width adjacent to a lower end of the recess and has a second width adjacent to an upper end of the recess, and the first width is wider than the second width.

17. The semiconductor device of claim 14, wherein the gate electrode comprises a portion extending on an uppermost surface of the active fin.

18. The semiconductor device of claim 12, wherein the side surface of the active fin is a first side surface, and the active fin further comprises a second side surface defining the recess, and the second side surface of the active fin is slanted with respect to the first direction in a plan view.

19. A semiconductor device comprising:
a first impurity region, a second impurity region, and a third impurity region spaced apart from each other;
a first active fin connecting the first and second impurity regions and comprising a first recess that extends through the first active fin in a width direction thereof;
a second active fin connecting the first and third impurity regions and comprising a second recess that extends through the second active fin in a width direction thereof;
a first gate electrode traversing the first active fin and comprising a first portion in the first recess of the first active fin and a second portion extending from the first portion onto a side surface of the first active fin;
a first gate insulating layer between the first active fin and the first gate electrode;
a second gate electrode traversing the second active fin and comprising a third portion in the second recess of the second active fin and a fourth portion extending from the third portion onto a side surface of the second active fin; and
a second gate insulating layer between the second active fin and the second gate electrode.

20. The semiconductor device of claim 19, wherein the second and third impurity regions are aligned along a first direction with the first impurity region interposed therebetween, and the first and second active fins extend in the first direction.

21. (canceled)

22. (canceled)

23. The semiconductor device of claim 12, wherein the side surface of the active fin comprises a portion onto which the second portion of the gate electrode extends, and the portion of the side surface of the active fin protrudes from an upper surface of the device isolation film.

24. The semiconductor device of claim 1, wherein the second portion of the gate electrode contacts the side surface of the active fin.
